(19) United States
(12) Patent Application Publication
(10) Pub. No.: US 2007/0268925 A1
(43) Pub. Date: Nov. 22, 2007

(54) Input buffer device and control method thereof

(75) Inventors: Gerald E. Sobelman, Minneapolis, MN (US); Dae-wook Kim, Minneapolis, MN (US); Man-ho Kim, Minneapolis, MN (US); Sang-woo Rhim, Seoul (KR); Eui-seok Kim, Suwon-si (KR); Beom-hak Lee, Seoul (KR)

Correspondence Address: SUGHRUE MION, PLLC, 2100 PENNSYLVANIA AVENUE, N.W., SUITE 800, WASHINGTON, DC, 20037, US

(73) Assignees: SAMSUNG ELECTRONICS CO., LTD.; REGENTS OF THE UNIVERSITY OF MINNESOTA

(21) Appl. No.: 11/434,189

(22) Filed: May 16, 2006

(51) Int. Cl. H04L 12/56; H04L 12/54

(52) U.S. Cl. 370/412; 370/428

(57) ABSTRACT

An input buffer device and control method of the input buffer device. The input buffer device includes a virtual output queuing (VOQ) buffering section which has a plurality of VOQ buffers. The input buffer device stores data which is input to an input port to a VOQ buffer corresponding to an intended output port of the data among the plurality of VOQ buffers. A shared buffering section is provided which stores the data when a VOQ buffer corresponding to the intended output port of the data is full of data. The stored data is forwarded to the VOQ buffer when the VOQ buffer is empty. Accordingly, the input buffer device can more efficiently process the data by use of the fixed-length FIFO buffers and the shared buffer.

### BACKGROUND OF THE INVENTION

1. Field of the Invention

Methods and apparatuses consistent with the present invention relate to input buffer devices and to controlling of the input buffer devices. More particularly, the present invention relates to an input buffer device that processes data more efficiently by use of first-in first-out (FIFO) buffers with a fixed length and a shared buffer, and a control method of the input buffer device.

2. Description of the Related Art

With the gradual convergence of computers, communications, broadcasts and the like, needs are converted from the existing application-specific integrated circuit (ASIC) and application-specific standard product (ASSP) to a system-on-chip (SoC). Additionally, the SoC industry has been expedited by the trend of information technology devices toward a light and simple structure and an intelligent function.

The SoC is a technology-intensive semiconductor which packages all system parts having various functions on a single chip. Active research is conducted on techniques to implement the SoC, particularly, on a scheme to interconnect intellectual property blocks (IPs) equipped on the chip.

Most techniques for the IP interconnections are based on a bus. However, such techniques increase the integration degree of the chip. The SoC based on the bus architecture is subject to structural limitations as the amount of information flow between IPs drastically increases.

To overcome the shortcomings of the SoC based on the bus architecture, a network-on-chip (NoC) technique is newly suggested, which interconnects the IPs by applying a general networking technology into a chip. The NoC in the SoC includes switches that transfer incoming packets to a destination according to a prescribed algorithm.

The switch on the NoC includes a plurality of input ports for receiving packets, and a plurality of output ports for outputting the packets. To avoid the head of line (HOL) blocking problem, an input buffer device (hereinafter, referred to as VoQ buffers) in each input port typically includes buffers used in a virtual output queuing (VOQ) scheme, as many as the output ports.

FIG. 1 schematically depicts an exemplary input buffer device equipped to an input port of a switch on a conventional NoC. More specifically, FIG. 1 shows the input buffer device provided to a switch (not shown) which includes five output ports (not shown).

Referring now to FIG. 1, the input buffer device 10 includes a classifier 11, a plurality of VOQ buffers 12a through 12e, and a scheduler 13. The classifier 11 stores packets incoming to the input buffer device 10 to a VOQ buffer which corresponds to an output port to which the packets are output. The scheduler 13 outputs the packets from the VOQ buffers 12a through 12e to the output port when the output port can process the packets.

The conventional VOQ scheme can address the HOL blocking problem, but requires as many VOQ buffers in the input buffer device of each input port as there are output ports in the switch. Accordingly, the area occupied by the input buffer device on the NoC increases.

The size of the buffer is limited because the network is not configured on the NoC like a conventional macro network router. Instead of the conventional input buffer device architecture which operates in the VOQ scheme by using only the FIFO buffers with the fixed depth, increasing demands are made for a new input buffer device architecture for efficiently processing data with a small buffer size.

### SUMMARY OF THE INVENTION

The present invention has been provided to address the above-mentioned and other problems and disadvantages occurring in the conventional arrangement, and an aspect of the present invention provides an input buffer device for efficiently processing data with fixed-length FIFO buffers and a shared buffer, and a control method of the input buffer device.

To achieve the above aspect of the present invention, an input buffer device includes a virtual output queuing (VOQ) buffering section which has a plurality of VOQ buffers and stores data which is input to an input port, to a VOQ buffer corresponding to an intended output port of the data among the plurality of VOQ buffers; and a shared buffering section which stores the data when a VOQ buffer corresponding to the intended output port of the data is full of data, and forwards the stored data to the VOQ buffer when the VOQ buffer is empty.

The input buffer device may further include a classification section which classifies and outputs the data which is input to the input port, based on the intended output port of the data; and a buffer manager which controls to store the data which is output from the classification section, to the shared buffering section when the VOQ buffer corresponding to the intended output port is full of data, and controls to stores the data which is stored in the shared buffering section, to the VOQ buffer when the VOQ is empty.

The shared buffering section may include a shared buffer which stores the data when the VOQ buffer corresponding to the intended output port of the data is full of data; a shared buffer classification section which selectively outputs the data which is output from the classification section, to the shared buffer or the VOQ buffering section under the control of the buffer manager; and a shared buffer selection section which selectively outputs data input from the shared buffer classification section and data input from the shared buffer to the VOQ buffering section under the control of the buffer manager.

The buffer manager may control the shared buffer selection section to output firstly data stored in the shared buffer to the VOQ buffer when the data stored in the shared buffer and data output from the shared buffer classification section have the same intended output port.

The buffer manager may send a signal to abort the data input to the input port when both the VOQ buffer corresponding to the intended output port of the data and the shared buffer are full of data.

The input buffer device may further include a scheduler which schedules and outputs the data stored in the VOQ buffering section, to an external switch means which switches the data to the intended output port, on a certain basis.

A switch device includes a plurality of input ports; a plurality of output ports; and a switch which outputs data input to one of the plurality of input ports, to an intended output port of the plurality of output ports. The switch device includes an input buffer device in each of the plurality of input ports, the input buffer device including a virtual output queuing (VOQ) buffering section which includes a plurality of VOQ buffers corresponding to the plurality of output ports, and stores the input data to a VOQ buffer corresponding to the intended output port of the data; and a shared buffering section which stores the input data when the VOQ buffer corresponding to the intended output port of the data is full of data, and forwards the stored data to the VOQ buffer when the VOQ buffer is empty.

The input buffer device may further include a classification section which classifies and outputs the input data based on the intended output port of the data; and a buffer manager which controls to store the data which is output from the classification section, to the shared buffering section when the VOQ buffer corresponding to the intended output port is full of data, and controls to stores the data which is stored in the shared buffering section, to the VOQ buffer when the VOQ is empty.

The shared buffering section may include a shared buffer which stores the data when the VOQ buffer corresponding to the intended output port of the data is full of data; a shared buffer classification section which selectively outputs the data which is output from the classification section, to the shared buffer and the VOQ buffering section under the control of the buffer manager; and a shared buffer selection section which selectively outputs data input from the shared buffer classification section and data input from the shared buffer to the VOQ buffering section under the control of the buffer manager.

The buffer manager may control the shared buffer selection section to output firstly data stored in the shared buffer to the VOQ buffer when the data stored in the shared buffer and data output from the shared buffer classification section have the same intended output port.

The buffer manager may send a signal to abort the data input to the input port when both the VOQ buffer corresponding to the intended output port of the data and the shared buffer are full of data.

The input buffer device may further include a scheduler which schedules and outputs the data stored in the VOQ buffering section, to the switch on a certain basis.

A control method of an input buffer device provided to an input port of a switch device including a switch which outputs data input to one of a plurality of input ports, to an intended output port of the data among a plurality of output ports, includes determining whether a virtual output queuing (VOQ) buffer corresponding to the intended output port of the input data is full of data when data input is requested from the input port; storing the input data in a shared buffer when the VOQ buffer is full of data; and storing the data stored in the shared buffer to the VOQ buffer when the VOQ buffer is empty.

The control method may further include storing the input data to the VOQ buffer when the VOQ buffer is empty.

The control method may further include outputting the data stored in the VOQ buffer, to the intended output port of the data.

The control method may further include determining whether the shared buffer is full of data; and sending a signal to abort the data input to the input port which requests the data input when the shared buffer is full of data.

### BRIEF DESCRIPTION OF THE DRAWING FIGURES

These and/or other aspects and advantages of the invention will become apparent and more readily appreciated from the following description of exemplary, non-limiting embodiments, taken in conjunction with the accompanying drawing figures of which:

FIG. 1 is a schematic diagram of an exemplary input buffer device provided to an input port of a switch on a conventional network-on-chip (NoC);

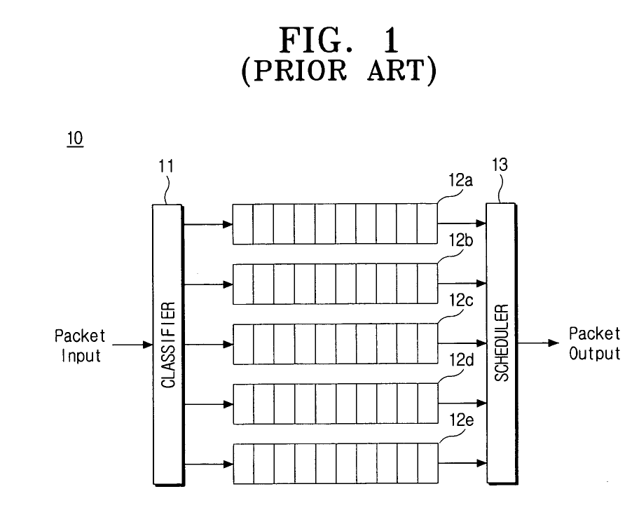

FIG. 2 is a schematic diagram of an exemplary switch according to a non-limiting embodiment of the present invention;

FIG. 3 is a block diagram of an input buffer device according to a non-limiting embodiment of the present invention; and

FIG. 4 is a flowchart outlining a control method of the input buffer device according to a non-limiting embodiment of the present invention.

### DETAILED DESCRIPTION OF THE EMBODIMENTS

Certain exemplary, non-limiting embodiments of the present invention will now be described in greater detail with reference to the accompanying drawings.

In the following description, the same drawing reference numerals are used for the same elements in different drawings. The matters defined in the description, such as detailed construction and element descriptions, are provided to assist in a comprehensive understanding of the invention. Also, well-known functions or constructions are not described in detail since they would obscure the invention in unnecessary detail.

According to a non-limiting embodiment of the present invention, more than one switch configures a network on a system-on-chip (SoC) so as to interface data transferred between intellectual property blocks (IPs) on the SoC. The switch is responsible for forwarding data packets received from its connected IP or from another adjacent switch, to a destination IP. Specifically, the switch forwards the received data packets directly to the destination IP when it is connected to the destination IP. Otherwise, when the switch is not connected to the destination IP, the switch forwards the data packet to an adjacent switch so that the data packets can be delivered to the destination IP.

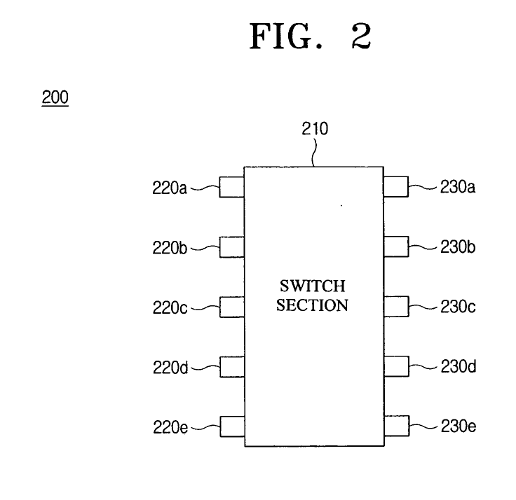

FIG. 2 is a schematic diagram of an exemplary switch device according to a non-limiting embodiment of the present invention.

The switch device 200 includes a plurality of input ports 220a through 220e, a plurality of output ports 230a through 230e, and a switching section 210. The switch device 200 can have as many input ports and output ports as its connected IPs and other switches.

The switch section 210 determines which output port 230a through 230e to output data packets to depending on a destination IP of the data packets incoming to the input ports 220a through 220e, and forwards the data packets to the determined output port.

The input ports 220a through 220e receive and store data packets from an IP connected to the switch device 200 or another switch, and forward the data packets to the corresponding output port via the switch section 210.

The input ports 220a through 220e each include an input buffer device (not shown) that includes virtual output queuing (VOQ) buffers (not shown) corresponding to the number of the output ports 230a through 230e of the switch device 200, and a shared buffer (not shown).

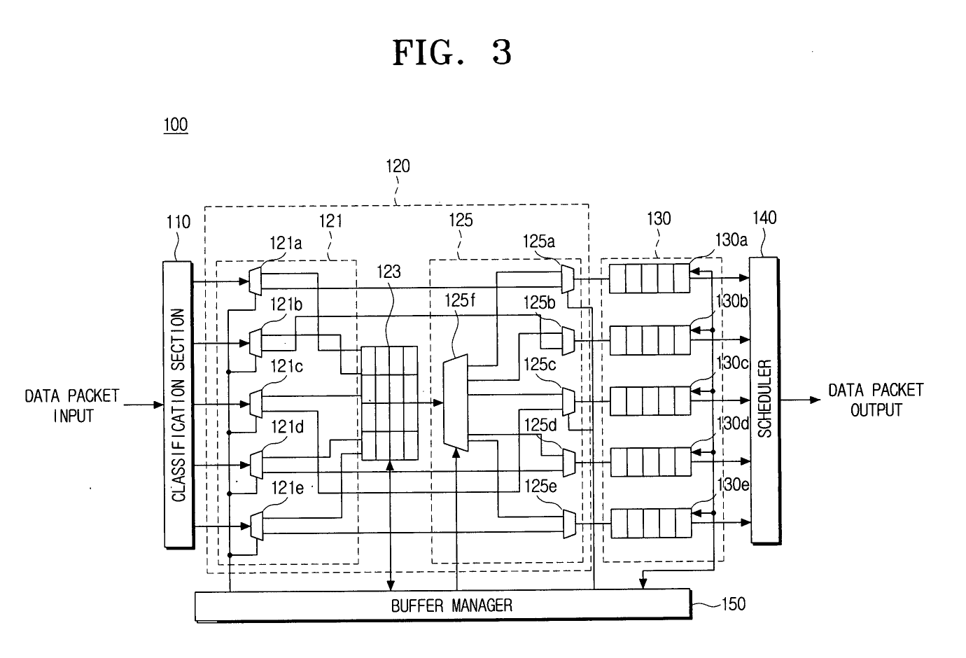

Hereafter, the input buffer device is explained in more detail in reference to FIG. 3. The input buffer device 100 includes a classification section 110, a shared buffering section 120, a VOQ buffering section 130, a scheduler 140, and a buffer manager 150. The shared buffering section 120 includes a shared buffer classification section 121, a shared buffer 123, and a shared buffer selection section 125. The shared buffer classification section 121 includes a plurality of classifiers 121a through 121e. The shared buffer selection section 125 includes a classifier 125f and a plurality of selectors 125a through 125e.

The VOQ buffering section 130 includes a plurality of VOQ buffers 130a through 130e. The number of the VOQ buffers 130a through 130e equipped in the input buffer device 100 is equal to the number of the output ports 230a through 230e of the switch device 200, as described above.

In a non-limiting embodiment of the present invention, the VOQ buffers 130a through 130e can be realized by first-in first-out (FIFO) buffers, and operate in a VOQ scheme. The VOQ buffering section 130 is equipped with the VOQ buffers 130a through 130e which correspond to the output ports 230a through 230e of the switch device 200, respectively, and stores the incoming data packets from the input ports 220a through 220e into the VOQ buffers 130a through 130e corresponding to the intended output ports 230 through 230e of the data packets.

In a non-limiting embodiment of the present invention, the depth of the VOQ buffers 130a through 130e can be less than the related art by use of the shared section 120, to be explained in detail.

The classification section 110 classifies and outputs the data packets input through the input ports 220a through 220e, based on the intended output ports 230a through 230e of the packets. For example, in case that the VOQ buffer 130a corresponds to the intended output port of the incoming data packets, the classification section 110 outputs the incoming data packets to the classifier 121a.

The shared buffering section 120, under the control of the buffer manager 150, temporarily stores the data packets when the VOQ buffer, corresponding to the intended output port of the data packets forwarded from the classification section 110, is full of data. When the VOQ buffer has enough space to store the data packets, the shared buffering section 120 provides the data packets to the VOQ buffer.

As aforementioned, the shared buffering section 120 includes the shared buffer classification section 121, the shared buffer 123, and the shared buffer selection section 130.

The shared buffer classification section 121, under the control of the buffer manager 150, forwards the data output from the classification section 110, to the shared buffer 123 or the shared buffer selection section 125 to deliver the data to the VOQ buffering section 130. The shared buffer classification section 121 is equipped with as many classifiers 121a through 121e as there are VOQ buffers 130a through 130e of the VOQ buffering section 130.

The classifier 121a through 121e selectively output the classified data packets, which are output from the classification section 110, to the shared buffer 123 or the shared buffer selection section 125 under the control of the buffer manager 150. For instance, when the VOQ buffer 130a corresponds to the intended output port of the incoming data packets, the classifier 121a selectively outputs the data packets output from the classification 110, to the shared buffer 123 or the selector 125a.

The shared buffer 123 serves to store the data packets which is output from the classification section 110, for the backup when the VOQ buffer corresponding to the destination of the data packets is full of data. The VOQ buffers 130a through 130e, in the VOQ buffering section 130, have limited storage capacity for data packets according to the output ports of the data packets. In comparison, the shared buffer 123 can store all data packets, which cannot be stored directly in the VOQ buffers 130a through 130e, without concerning the storage capacity limitation.

The shared buffer selection section 125, under the control of the buffer manager 150, selectively outputs the data input from the shared buffer classification section 121 and the data input from the shared buffer 123, to the VOQ buffering section 130. The shared buffer selection section 125 includes the classifier 125f and the plurality of selectors 125a through 125e.

The classifier 125f, under the control of the buffer manager 150, classifies the backup data packets in the shared buffer 123 based on the intended output ports of the data packets, and selectively outputs the classified data packets to the selectors 125a through 125e which are connected to the VOQ buffers 130a through 130e corresponding to the intended output ports. For instance, when the data packets output from the shared buffer 123 is to be transferred to the VOQ buffer 130a, the classifier 125f outputs the data packets to the selector 125a.

The selectors 125a through 125e, under the control of the buffer manager 150, selectively output the data from the shared buffer 123 or the data from the shared buffer classification section 121, to the VOQ buffering section 130. Particularly, when the data packets from the shared buffer 123 and the shared buffer classification section 121 are to be output to an identical VOQ buffer, the selectors 125a through 125e output the data packets from the shared buffer 123 to the VOQ buffer first.

The buffer manager 150 controls the shared buffer 123 to store the data packets output from the classification section 110 when the VOQ buffer corresponding to the intended output port is full of data, and controls the shared buffering section 120 to forward the data packets stored in the shared buffer 150 to the VOQ buffer when the VOQ buffer is empty. To this end, the buffer manager 150 checks whether the shared buffer 123 and the VOQ buffers 130a through 130e are full of data or not.

When the data packets stored in the shared buffer 123 and the data packets output from the shared buffer classification section 121 are to be output to the identical output port, the buffer manager 150 controls the shared buffer selection section 125 to firstly output the data packet stored in the shared buffer 123 to the VOQ buffer corresponding to the intended output port of the data packet.

When both of the VOQ buffers corresponding to the intended output port of the data packets and the shared buffer 123 are full of data, the buffer manager 150 prevents the loss of the data packets by transferring a signal to request the abortion of the data packet input to the input ports.

The scheduler 140 schedules on a certain basis and outputs the data packets stored in the VOQ buffers 130a through 130e of the VOQ buffering section 130, to the switch 210 which switches the data packets to the corresponding output ports 230a through 230e.

As constructed and configured above, the input buffer device 100 minimizes the depth of the VOQ buffers, which have a limitation on the storable data packets according to the intended output ports, in a manner that is less than the related art, by utilizing the shared buffer which can store data packets for the backup regardless of the intended output ports of the data packets.

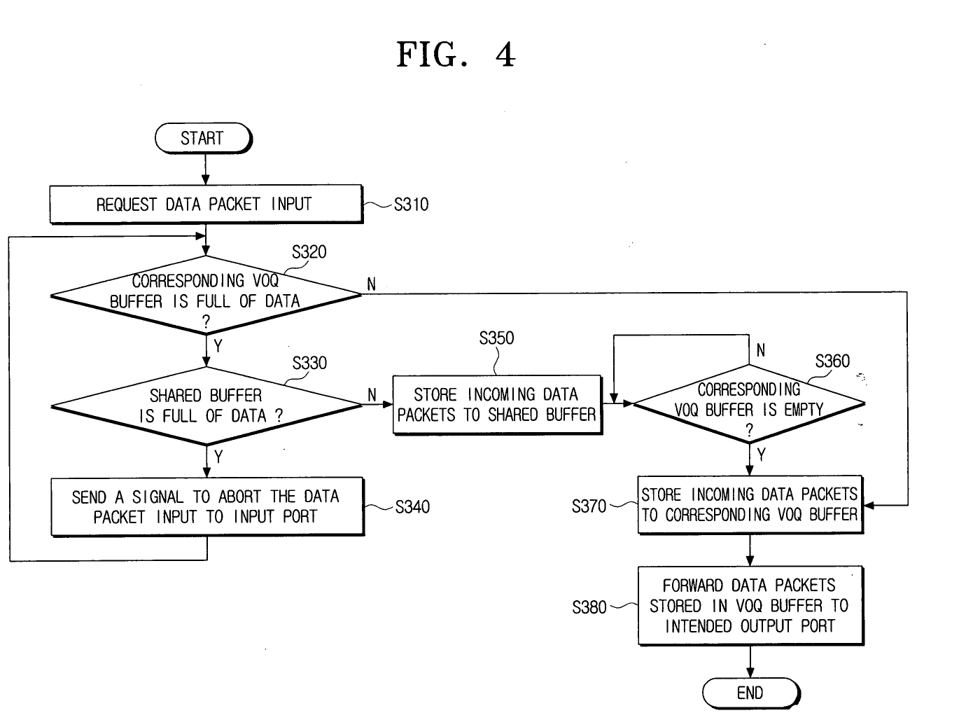

FIG. 4 is a flowchart outlining a control method of the input buffer device according to a non-limiting embodiment of the present invention.

Referring to FIGS. 3 and 4, upon receiving a request of the data packet input from an input port (not shown) (S310), the buffer manager 150 checks whether a VOQ buffer corresponding to an intended output port of the data packets is full of data (S320).

When the corresponding VOQ buffer is full of data (S320-Y), the buffer manager 150 checks whether the shared buffer 123 is full of data or not (S330).

When the shared buffer 123 is full of data (S330-Y), the buffer manager 150 prevents the loss of the data packets by transferring to the input port a signal indicating to abort the input of the data packets (S340).

In contrast, when the shared buffer 123 is not full of data (S330-N), the buffer manager 150 controls the shared buffer classification section 121 to forward the incoming data packets to the shared buffer 123 to store them (S350).

Next, the buffer manager 150 checks whether the VOQ buffer corresponding to the intended output port of the data packets stored in the shared buffer 123 is empty or not (S360). When the VOQ buffer is empty (S360-Y), the buffer manager 150 controls the shared buffer selection section 125 to store the incoming data packets in the VOQ buffer (S370).

When the VOQ buffer is not full of data (S320-N), the buffer manager 150 controls the shared buffering section 120 to store the incoming data packets in the VOQ buffer which corresponds to the intended output port of the data packets (S370).

The scheduler 140 schedules on a specific basis and forwards the data packets stored in the VOQ buffers 130a through 130e of the VOQ buffering section 130 in operations S310 to S370, to the switch 210 which switches the data packets to the intended output ports (S380).

As set for above, by use of the shared buffer for storing the data packets for the backup, regardless of the intended output port of the data packets, it is possible to minimize the depth of the VOQ buffers having the limited data packet storage according to the intended output ports.

Therefore, the size of the buffers employed in the input buffer device can be minimized and the area occupied by the input buffer device in the NoC also can be minimized.

While the present invention has been particularly shown and described with reference to exemplary, non-limiting embodiments thereof, it will be understood by those skilled in the art that various changes in form and details may be made therein without departing from the spirit and scope of the invention as defined by the appended claims.

What is claimed is:

1. An input buffer device comprising:
a virtual output queuing (VOQ) buffering section having a plurality of VOQ buffers, the VOQ buffering section operative to store data input to an input port to a VOQ buffer corresponding to an intended output port of the data among the plurality of VOQ buffers; and
a shared buffering section operative to store the data when a VOQ buffer corresponding to the intended output port of the data is full of data, the shared buffering section operative to forward the stored data to the VOQ buffer when the VOQ buffer is empty.

2. The input buffer device of claim 1, further comprising:
a classification section operative to classify and output the data input to the input port, based on the intended output port of the data; and
a buffer manager operative to control storage of the data which is output from the classification section to the shared buffering section, when the VOQ buffer corresponding to the intended output port is full of data, and the buffer manager is operative to control movement of the data stored in the shared buffering section to the VOQ buffer when the VOQ buffer is empty.

3. The input buffer device of claim 1, wherein the shared buffering section comprises:
a shared buffer operative to store the data when the VOQ buffer corresponding to the intended output port of the data is full of data;
a shared buffer classification section operative to selectively output the data, which is output from a classification section for classifying the data input from the input port based on the intended output port of the data, to the shared buffer or the VOQ buffering section; and
a shared buffer selection section operative to selectively output data input from the shared buffer classification section and data input from the shared buffer to the VOQ buffering section

4. The input buffer device of claim 2, wherein the buffer manager controls such that data stored in the shared buffer is firstly output to the VOQ buffer when the data stored in a shared buffer, operative to store the data when the VOQ buffer corresponding to the intended output port of the data is full of data, and data output from a shared buffer classification section, operative to selectively output the data, which is output from a classification section for classifying the data input to the input port based on the intended output port of the data, to the shared buffer and the VOQ buffering section, have the same intended output port.

5. The input buffer device of claim 2, wherein the buffer manager is operative to send a signal to abort the data input to the input port when both the VOQ buffer corresponding to the intended output port of the data and a shared buffer, operative to store the data when the VOQ buffer corresponding to the intended output port of the data is full of data, are full of data.

6. The input buffer device of claim 1, further comprising:
a scheduler operative to schedule and output the data stored in the VOQ buffering section, to an external switch means which switches the data to the intended output port.

7. A switch device comprising:
a plurality of input ports;
a plurality of output ports; and
a switch operative to output data input to one of the plurality of input ports to an intended output port of the plurality of output ports,
wherein the switch device includes an input buffer device in each of the plurality of input ports, the input buffer device comprising:
a virtual output queuing (VOQ) buffering section which includes a plurality of VOQ buffers corresponding to the plurality of output ports, the VOQ buffering section operative to store the input data to a VOQ buffer corresponding to the intended output port of the data; and
a shared buffering section operative to store the input data when the VOQ buffer corresponding to the intended output port of the data is full of data, and the shared buffering section operative to forward the stored data to the VOQ buffer when the VOQ buffer is empty.

8. The switch device of claim 7, wherein the input buffer device further comprises:
a classification section operative to classify and output the input data based on the intended output port of the data; and
a buffer manager operative to control storage of the data which is output from the classification section to the shared buffering section, when the VOQ buffer corresponding to the intended output port is full of data, and the buffer manager operative to control movement of the data stored in the shared buffering section to the VOQ buffer when the VOQ buffer is empty.

9. The switch device of claim 7, wherein the shared buffering section comprises:
a shared buffer operative to store the data when the VOQ buffer corresponding to the intended output port of the data is full of data;
a shared buffer classification section operative to selectively output the data, which is output from a classification section for classifying the data input to the input port based on the intended output port of the data, to the shared buffer or the VOQ buffering section; and
a shared buffer selection section operative to selectively output data input from the shared buffer classification section and data input from the shared buffer to the VOQ buffering section under the control of the buffer manager.

10. The switch device of claim 8, wherein the buffer manager controls such that data stored in the shared buffer to is firstly output the VOQ buffer when the data stored in a shared buffer, operative to store the data when the VOQ buffer corresponding to the intended output port of the data is full of data, and data output from a shared buffer classification section, operative to selectively output the data, which is output from the classification section for classifying the data input to the input port based on the intended output port of the data, to the shared buffer or the VOQ buffering section, have the same intended output port.

11. The switch device of claim 8, wherein the buffer manager is operative to send a signal to abort the data input to the input port when both the VOQ buffer corresponding to the intended output port of the data and a shared buffer, operative to store the data when the VOQ buffer corresponding to the intended output port of the data is full of data, are full of data.

12. The switch device of claim 7, wherein the input buffer device further comprises:
a scheduler operative to schedule and output the data stored in the VOQ buffering section, to the switch on a certain basis.

13. A control method of an input buffer device provided to an input port of a switch device including a switch which outputs data input to one of a plurality of input ports to an intended output port of the data among a plurality of output ports, the method comprising:
determining whether a virtual output queuing (VOQ) buffer corresponding to the intended output port of the input data is full of data when data input is requested from the input port;
storing the input data in a shared buffer when the VOQ buffer is full of data; and
storing the data stored in the shared buffer to the VOQ buffer when the VOQ buffer is empty.

14. The control method of claim 13, further comprising:
storing the input data to the VOQ buffer when the VOQ buffer is empty.

15. The control method of claim 13, further comprising:
outputting the data stored in the VOQ buffer to the intended output port of the data.

16. The control method of claim 13, further comprising:
determining whether the shared buffer is full of data; and
sending a signal to abort the data input to the input port which requests the data input when the shared buffer is full of data.
